(19) United States
(12) Patent Application Publication
(10) Pub. No.: US 2025/0201748 A1
(43) Pub. Date: Jun. 19, 2025

(54) LOW PROFILE DIE TERMINAL WITH BALL DROP SOLDER

(71) Applicant: Texas Instruments Incorporated, Dallas, TX (US)

(72) Inventors: Jomari Austria, Malabon City (PH); Jeffrey Solas, Iloilo City (PH)

(21) Appl. No.: 18/544,997

(22) Filed: Dec. 19, 2023

(51) Int. Cl. H01L 23/00

(52) U.S. Cl. CPC H01L 24/13; H01L 24/05; H01L 24/11; H01L 2224/0219; H01L 2224/0401; H01L 2224/05124; H01L 2224/05647; H01L 2224/11462; H01L 2224/13111; H01L 2224/13139; H01L 2224/13147

(57) ABSTRACT

An electronic device includes a semiconductor die with a surface layer, a metallization structure on the surface layer, a conductive terminal with a metal post and having a first side contacting a side of a conductive feature of the metallization structure, and a solder cap on a second side of the conductive terminal. A method includes forming a copper layer on a portion of a conductive feature of a metallization structure of a wafer, forming a metal post on a first portion of the copper layer, etching a second portion of the copper layer, performing a solder ball drop process that forms a solder cap on a side of the metal post, and separating from the wafer, a die that includes the metal post and the solder cap.

### BACKGROUND

Power conversion components and other high power electronic devices are used in a variety of applications that increasingly call for compact small form factors with increased power density, such as cell phones, mobile device chargers, industrial power conversion systems, etc. Wafer chip scale packages (WCSP) often provide die interconnections by large solder balls, but this inhibits the ability to lower the die height and the resulting packaged electronic device size.

### SUMMARY

In one aspect, an electronic device includes a semiconductor die with a semiconductor surface layer, a metallization structure on a side of the semiconductor surface layer and including a conductive feature, a conductive terminal having a metal post, the conductive terminal having a first side contacting a side of the conductive feature, and a solder cap on a second side of the conductive terminal.

In another aspect, a system includes a circuit board and an electronic device attached to the circuit board. The electronic device includes a semiconductor die with a semiconductor surface layer, a metallization structure on a side of the semiconductor surface layer and including a conductive feature, a conductive terminal having a metal post, the conductive terminal having a first side contacting a side of the conductive feature, and a solder cap on a second side of the conductive terminal, where the second side of the conductive terminal is soldered to a lead frame or substrate and the lead frame or substrate is electrically connected to the circuit board.

In a further aspect, a method of fabricating an electronic device includes forming a copper layer on a portion of a conductive feature of a metallization structure of a wafer, performing an electroplating process (700) that forms a metal post on a first portion of the copper layer, etching a second portion of the copper layer, performing a solder ball drop process that forms a solder cap on a side of the metal post, and separating from the wafer, a die that includes the metal post and the solder cap.

### BRIEF DESCRIPTION OF THE DRAWINGS

FIG. 1 is a partial side elevation view of an electronic device with a low profile metal post terminal on a metallization conductive feature with a ball drop solder ball.

FIG. 1A is a partial side view of a system with the electronic device of FIG. 1 mounted to a circuit board.

FIG. 2 is a flow diagram of a method of fabricating an electronic device.

FIGS. 3-11A are partial sectional side elevation views of a wafer undergoing processing according to the method of FIG. 2.

FIGS. 12 and 12A are partial side and perspective views of the wafer undergoing die separation processing according to the method of FIG. 2.

FIGS. 13-16 are partial sectional side elevation views of packaging processing according to the method of FIG. 2.

### DETAILED DESCRIPTION

In the drawings, like reference numerals refer to like elements throughout, and the various features are not necessarily drawn to scale. Also, the term “couple” or “couples” includes indirect or direct electrical or mechanical connection or combinations thereof. For example, if a first device couples to or is coupled with a second device, that connection may be through a direct electrical connection, or through an indirect electrical connection via one or more intervening devices and connections. One or more operational characteristics of various circuits, systems and/or components are hereinafter described in the context of functions which in some cases result from configuration and/or interconnection of various structures when circuitry is powered and operating. In the following discussion and in the claims, the terms “including”, “includes”, “having”, “has”, “with”, or variants thereof are intended to be inclusive in a manner similar to the term “comprising”, and thus should be interpreted to mean “including, but not limited to”.

Unless otherwise stated, “about,” “approximately,” or “substantially” preceding a value means +/−10 percent of the stated value. One or more operational characteristics of various circuits, systems and/or components are hereinafter described in the context of functions which in some cases result from configuration and/or interconnection of various structures when circuitry is powered and operating. One or more structures, features, aspects, components, etc., may be referred to herein as first, second, third, etc., such as first and second terminals, first, second, and third, wells, etc., for case of description in connection with a particular drawing, where such are not to be construed as limiting with respect to the claims. Various disclosed structures and methods of the present disclosure may be beneficially applied to manufacturing an electronic device such as an integrated circuit. While such examples may be expected to provide various improvements, no particular result is a requirement of the present disclosure unless explicitly recited in a particular claim.

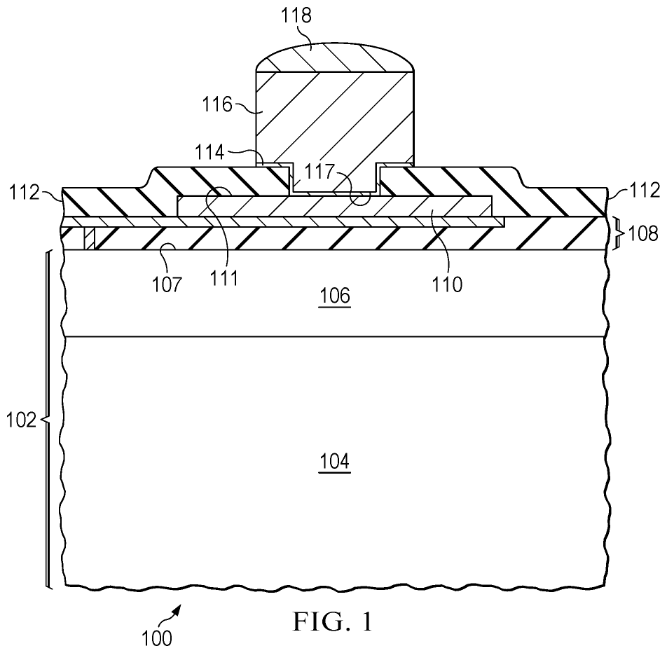

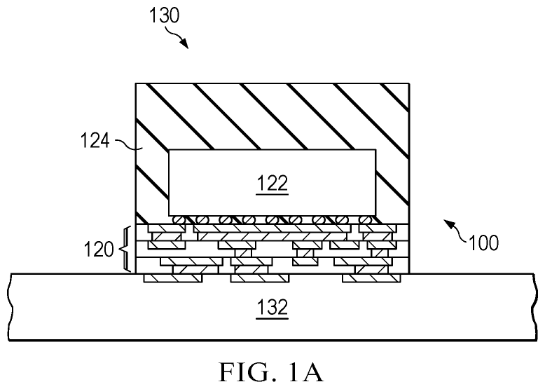

Referring initially to FIGS. 1 and 1A, disclosed examples include an electronic device 100 with a semiconductor die 122 (FIG. 1A) having a low electronic device height to facilitate compact small form factor power converters and other electronic system applications. FIG. 1 shows a portion of the electronic device 100 during processing as a wafer 102 prior to separation of the die 122, and FIG. 1A shows the electronic device 100 including the separated die 122 in a package structure installed on a system circuit board. As shown in FIG. 1, the electronic device 100 has a silicon substrate layer 104 and a semiconductor surface layer 106 on the substrate layer 104. In one example, the semiconductor surface layer 106 is or includes gallium nitride (GaN) with an upper or top side 107. In another example, the semiconductor surface layer 106 is or includes a different type of semiconductor material, such as silicon. One or more electronic components, such as transistors, diodes, resistors, etc. (not shown) can be formed on and/or in the semiconductor surface layer 106 to provide an electronic component and/or circuit of the electronic device.

As further shown in FIG. 1, the electronic device 100 includes a single or multilevel metallization structure 108 that includes one or more conductive features. The metallization structure 108 can include one or more patterned conductive metal traces and/or conductive metal vias, such as aluminum, copper, or other suitable conductive metal or alloy thereof with a dielectric material formed around the conductive metal structures. In the illustrated example, the metallization structure 108 includes a conductive feature 110 connected to a metal trace feature in an uppermost level of the metallization structure 108. In one implementation, the conductive feature 110 is or includes aluminum. In another implementation, the conductive feature 110 can be a different conductive metal.

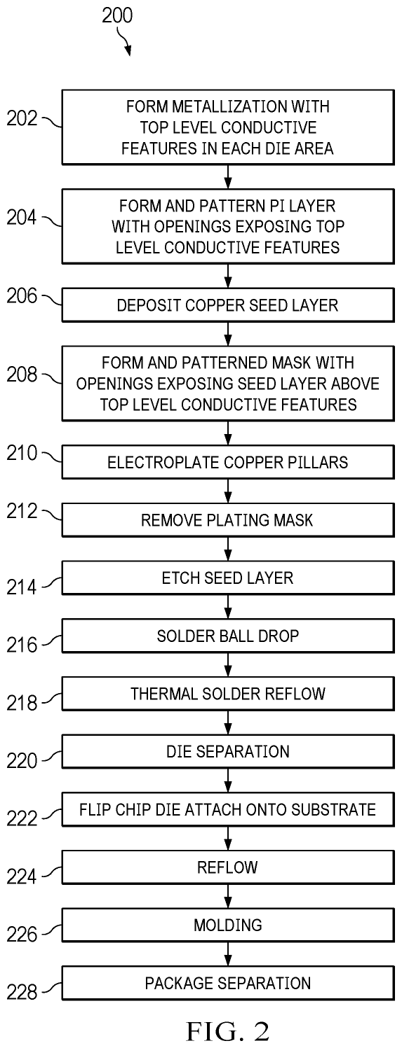

The electronic device 100 includes conductive metal terminals that provide electrical and mechanical interconnection for the circuit or component of the device 100, one of which is shown in FIG. 1. FIG. 1A shows an example system 130, in which the semiconductor die 122 of the electronic device 100 includes multiple terminals soldered to conductive features of an upper level of a multilevel package substrate 120. In this example, conductive features or leads along the bottom level of the multilevel package substrate 120 are soldered to conductive metal pads of a printed circuit board 132. The packaged electronic device 100 in FIG. 1A also includes a molded or ceramic package structure 124 that encloses all or part of the semiconductor die 122 and extends onto the upper portions of the multilevel package substrate 120 in the illustrated example. The die terminals of the electronic device 100 in one example are or include copper posts (e.g., pillars) with solder caps. In one example, moreover, the solder caps are formed by solder ball drop processing as discussed further below in connection with FIG. 2.

In one example, a polyimide layer 112 extends on a portion of the conductive feature 110 of the metallization structure 108 and is in contact with and covers outer portions of the top side 111 of the conductive feature 110 as shown in FIG. 1. The illustrated conductive terminal in FIG. 1 includes a metal post 116 with a bottom or first side 117 that contacts a portion of the top side 111 of the conductive feature 110. In one example, the metal post 116 is or includes copper. In another example, a different conductive metal can be used. In one example, the conductive terminal includes a layer of sputtered titanium or titanium-tungsten as barrier layer alloy followed by a copper layer 114, referred to as a seed layer, that extends between the metal post 116 and the conductive feature 110 of the metallization structure 108. In one example, the copper layer 114 and any included barrier layer alloy is much thinner than the metal post 116, although any suitable thickness can be used. In this example, a bottom surface of the copper layer 114 (and any included barrier layer) forms the bottom side 117 of the conductive terminal and is in contact with a portion of the top side 111 of the conductive feature 110 of the metallization structure 108. The polyimide layer 112 in this example contacts a portion of the copper layer 114 and make contact with a portion of the metal post 116, although not a strict requirement of all possible implementations.

A solder cap 118 extends on a top or second side of the conductive terminal 114, 116. The vertical height of the metal post 116 can be any suitable thickness to provide thermal isolation to the semiconductor die 122, for example, approximately 35 to 50 μm in in one example using a gallium nitride semiconductor surface layer 106. Significantly taller metal posts 116 can be used, but this creates difficulty with respect to coplanarity of the top or second sides of multiple terminals for a given die 122. In this regard, lower terminal heights can beneficially facilitate small form factor semiconductor dies 122 and help reduce the overall height of the packaged electronic device 100 to accommodate small form factor applications.

Unlike wafer chip scale packaging approaches using large solder ball terminals, the metal post contacts of the electronic device 100 provide a small form factor solder capped conductive metal terminal for mechanically and electrically interconnecting the die 122 to a host structure, such as the multilevel package substrate 120 of FIG. 1A. In another example, the electronic device 100 can include conductive metal features of a starting lead frame (not shown) with the solder capped conductive metal terminals 114, 116, 118 connected to corresponding conductive features of a starting lead frame during electronic device packaging operations. In addition, the use of metal posts (e.g., pillars) 116 facilitates lateral reduction in the dimensions of the semiconductor die 122 by enabling inclusion of more terminals in a given area compared with larger solder ball terminals.

In one example, moreover, the solder cap 118 of the conductive terminals is formed by a solder ball drop process described further hereinafter, which facilitates cost effective manufacturing compared with plated solder caps. In this or another example, the solder cap 118 includes copper (Cu), tin (Sn) and silver (Ag) (e.g., sometimes referred to as “SAC” solder). Plated solder approaches, in contrast, cannot provide solder that includes copper. The solder ball drop fabrication of the solder caps 118 in the illustrated example provides more uniform solder material composition than plated solder approaches. In addition, the ball drop solder caps 118 have better electromigration performance and thus facilitate use in higher voltage circuits and system applications, particularly in combination with high or medium voltage transistors or other power conversion components of the semiconductor die 122 (e.g., GaN transistors, etc.). In one example, the solder cap 118 includes SAC305/396 solder with a nonzero copper composition along with tin and silver, whereas plated solder as little or no copper in the solder, especially in the topmost part after soldering to a host structure.

In addition, the example conductive terminal structures of the present examples do not include an intervening separate copper layer (e.g., sometimes referred to as a “copper over anything (COA) layer, where the bottom side 117 of the terminal (the metal post 116 alone with or without the seed layer 114) contacts the top side 111 of the conductive feature 110 to provide a low profile compact terminal structure for power delivery and other small form factor system applications, such as the example system 130 of FIG. 1A.

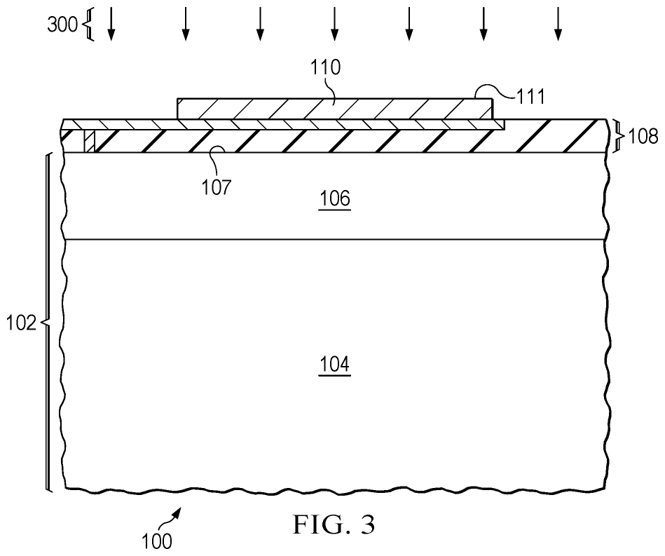

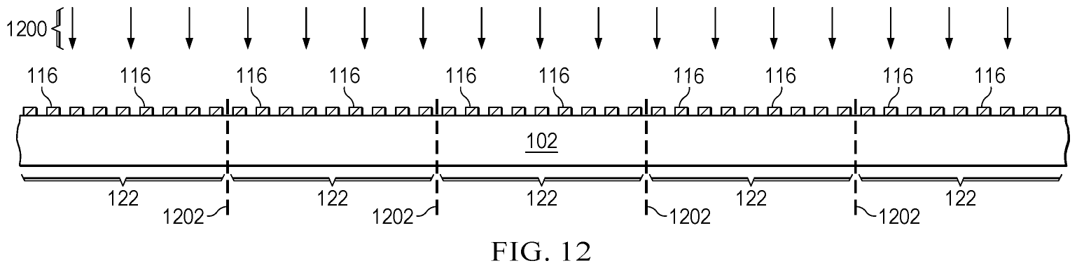

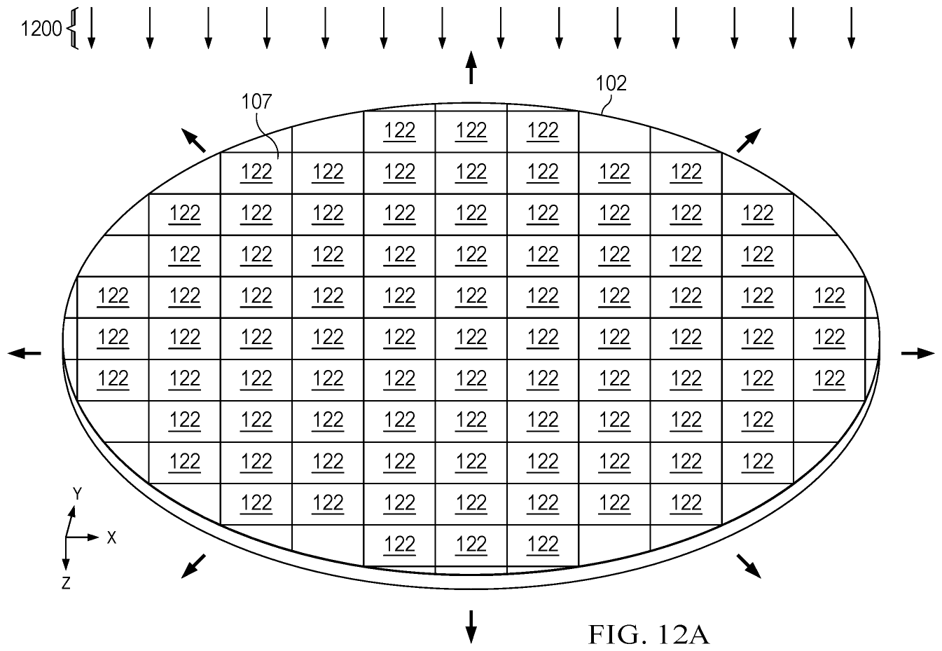

Referring also to FIGS. 2-16, FIG. 2 shows a method 200 of fabricating an electronic device, FIGS. 3-11A show a wafer undergoing processing to form the conductive terminals described above according to the method of FIG. 2, and FIGS. 12-16 show the illustrated semiconductor die 122 being separated from the starting wafer and packaged to create the packaged electronic device 100 of FIG. 1A in one example.

The method 200 begins at 202 in FIG. 2 with a wafer having previously undergone various fabrication steps to form one or more electronic components in each unit area of the starting wafer. In one example, the wafer includes a gallium nitride (GaN) semiconductor surface layer 106. A single or multilevel metallization structure is formed at 202 in FIG. 2 with one or more upper or top-level conductive features in each unit area. FIG. 3 shows one example, in which a metallization process 300 is performed on a processed wafer 102. The metallization process 300 forms the metallization structure 108 described above including one or more conductive metal trace features, via features (not shown) and one or more levels of intervening dielectric material. The process 300 and FIG. 3 includes forming the aluminum conductive feature 110 (e.g., aluminum) with a top side 111 as described above in connection with FIG. 1.

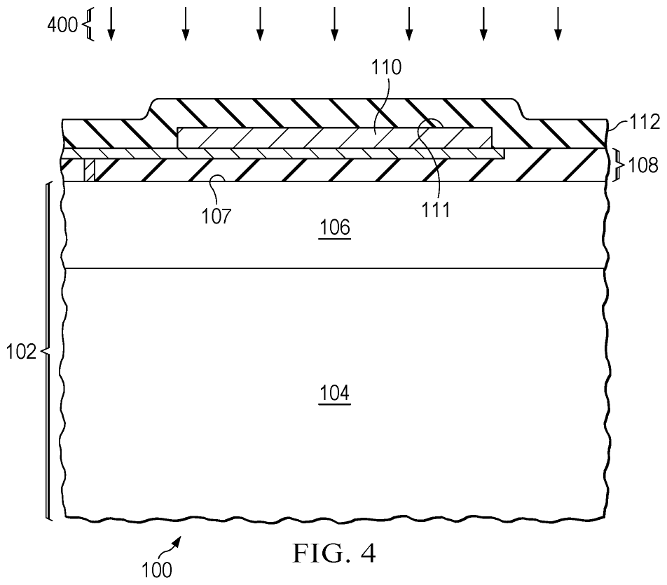

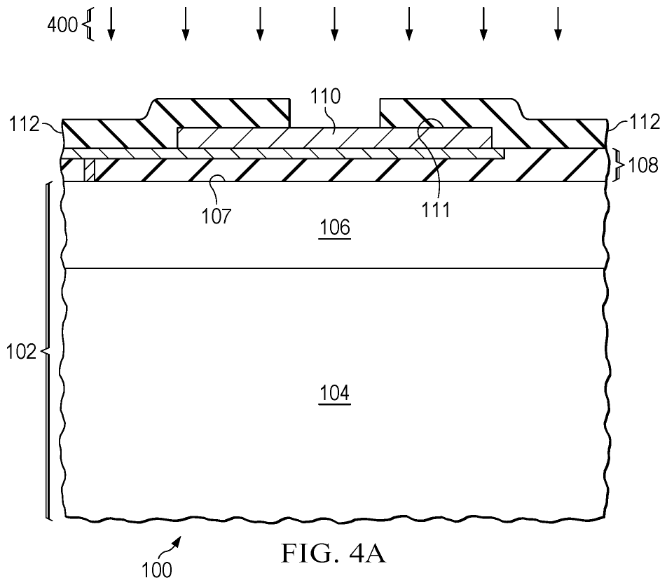

The illustrated example also includes forming one or more protective layers, such as a polyimide (PI) layer at 204 in FIG. 2. FIGS. 4 and 4A show one example, in which a process 400 is performed that forms the polyimide layer 112 extending over the top side of the metallization structure 108, including covering the top side 111 of the conductive metal feature 110. In one example, the process 400 includes a blanket polyamide deposition to initially form the polyimide layer 112 as shown in FIG. 4. The process 400 in this example also includes patterning operations to form an opening in the polyimide layer 112 that exposes a portion of the top side 111 of the conductive feature 110 as shown in FIG. 4A.

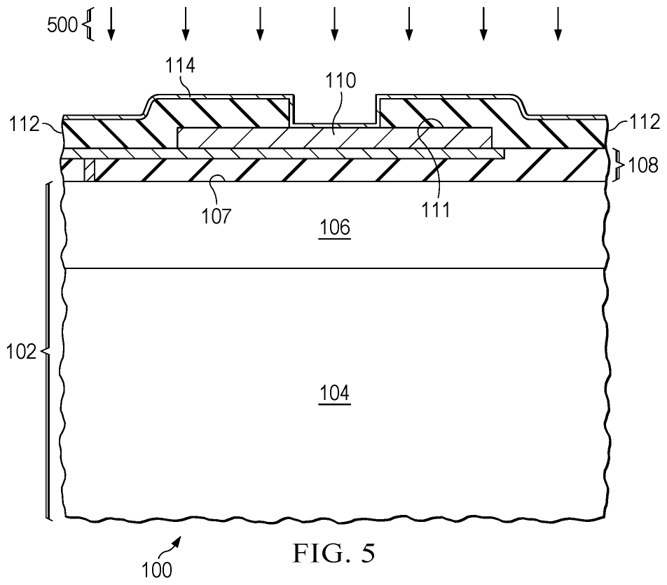

The method 200 continues with metal terminal formation at 206-214 in FIG. 2 to form a conductive metal terminal that contacts the exposed portion of the conductive feature 110 of the metallization structure 108. The illustrated example begins at 206 with copper seed layer deposition. FIG. 5 shows one example, in which a sputtering or other deposition process 500 is performed that forms the initial copper seed layer 114 that extends on the top side of the polyimide layer 112. The copper seed layer in this example also extends on the patterned sidewalls of the opening of the polyimide layer 112 and onto the exposed portion of the top side 111 of the conductive feature 110 of the metallization structure 108. In one example, the seed layer deposition process 500 is a spider deposition process that deposits the copper seed layer 114, for example, including an initial titanium layer of approximately 1000 Å or a titanium-tungsten layer of approximately 3000 Å and a copper layer of approximately 2000 Å.

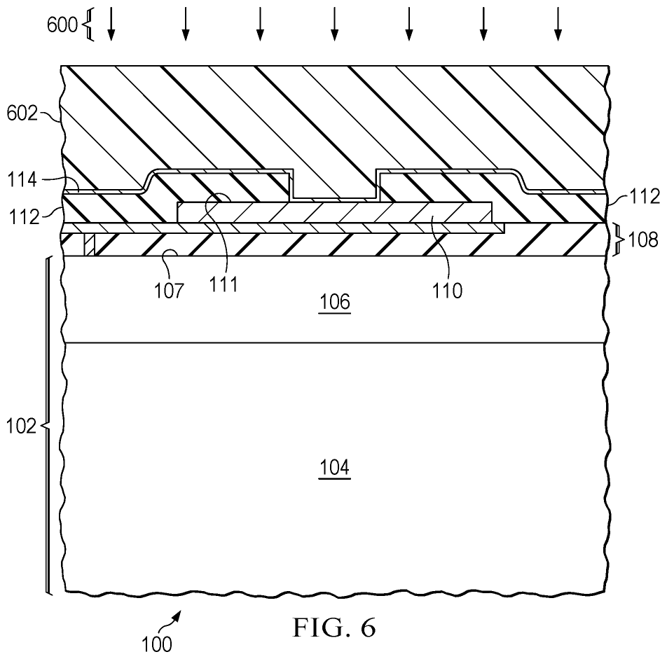

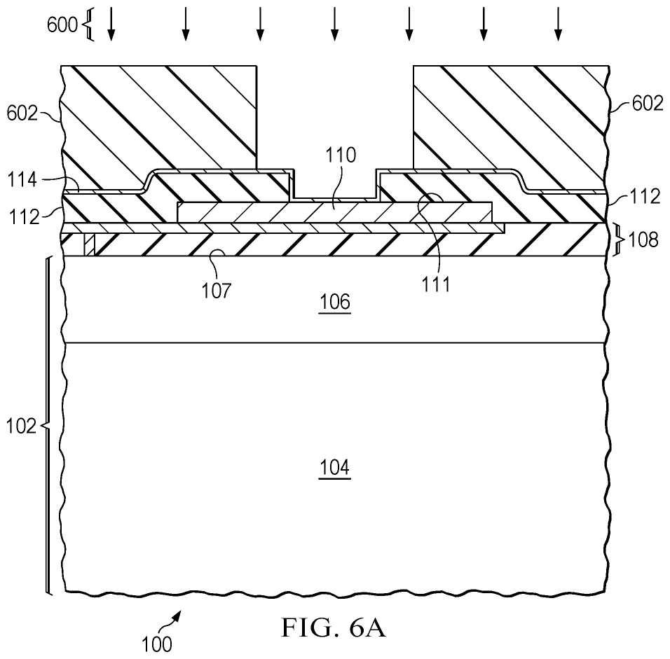

At 208 in FIG. 2, the illustrated example continues with forming and patterning a mask with openings that expose a portion of the seed layer 114 above the top level conductive features 110 in each unit area of the processed wafer. FIGS. 6 and 6A show one example, in which a process 600 is performed that deposits a plating mask layer 602 on the top side of the wafer. In one example, the mask 602 is a photo resist layer (e.g., CE7000). In another example, any suitable nonconductive mask layer material can be used in order to facilitate a subsequent electroplating process. The mask layer 602 initially covers the entire copper seed layer 114, including the seed layer 114 on the conductive feature 110 in the opening of the polyimide layer 112 as shown in FIG. 6. The process 600 continues in FIG. 6A with patterning the mask layer 602 to create an opening in each prospective terminal region of each unit area of the processed wafer that exposes the copper seed layer 114 in the opening of the polyimide layer 112.

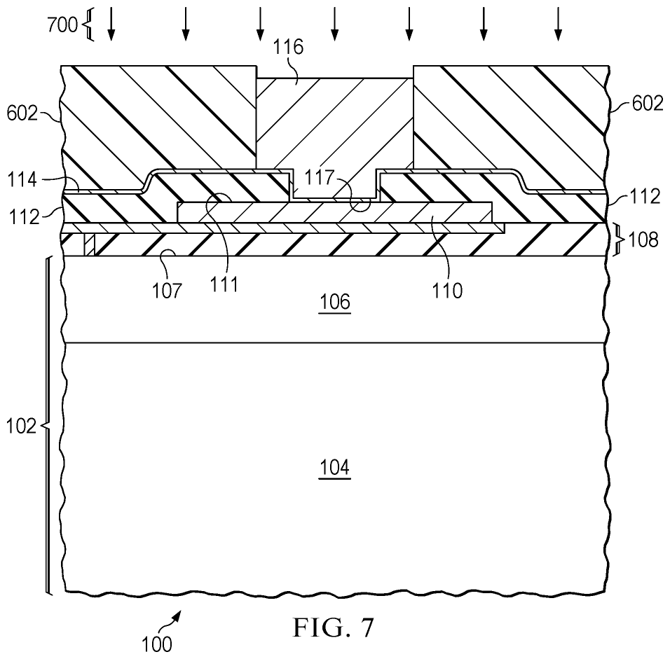

The method 200 continues at 210 in FIG. 2 with electroplating to form the metal posts 116 (e.g., pillars) over first portions of the copper seed layer 114. FIG. 7 shows one example, in which an electroplating process 700 is performed that forms the metal post 116 in the opening of the plating mask 602. In one example, the electroplating process 700 continues until the height of the conductive metal post 116 exceeds a desired final terminal height, for example, approximately 35 to 50 μm, with an additional thickness generally corresponding to the thickness of the copper seed layer 114. This allows subsequent copper etching to remove remnant portions of the copper seed layer 114 to yield a desired final height of the metal post 116 for a given electronic device design.

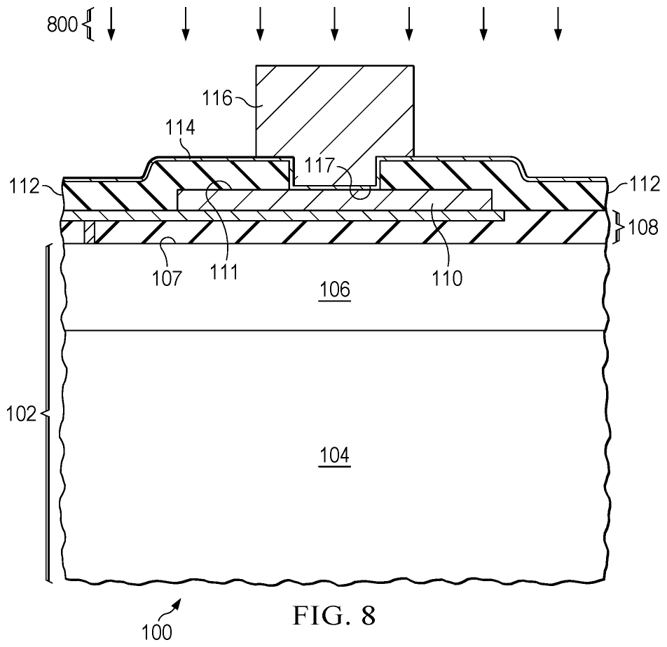

The plating mask layer is then removed at 212 in FIG. 2. FIG. 8 shows one example, in which a photo resist strip or cleaning process 800 is performed that removes the remnant portions of the plating mask.

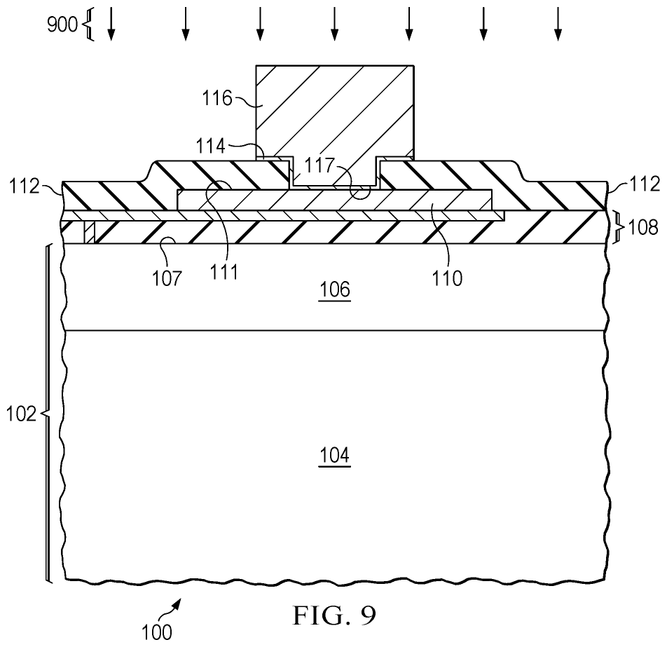

The method 200 continues at 214 in FIG. 2 with seed layer etching. FIG. 9 shows one example, in which a etch process 900 is performed that etches the exposed portions of the copper seed layer 114 and the metal post 116. The etch process 900 is performed until the exposed first portions of the copper seed layer 114 are removed from the top sides of the polyimide layer, and the process 900 may remove a corresponding amount of the plated metal post 116, while leaving the first portions of the copper seed layer 114 under the metal post 116, including the bottom side 117 of the metal terminal structure.

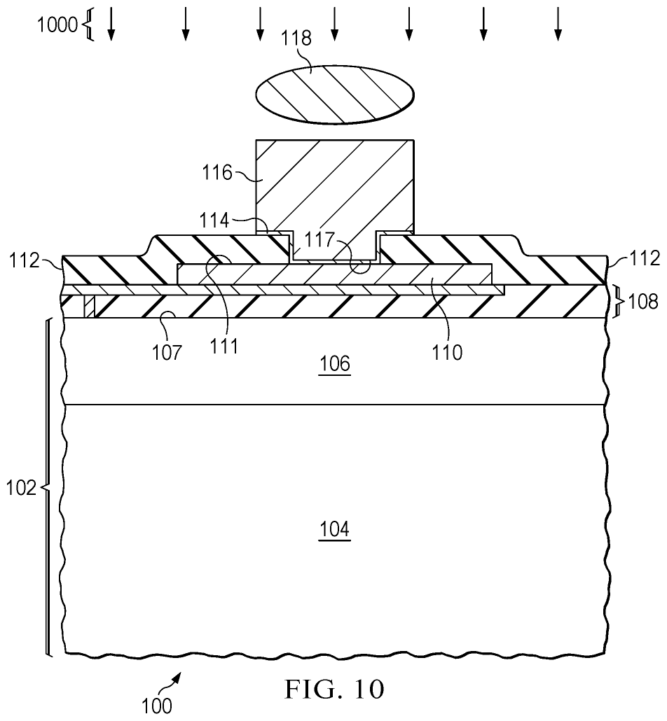

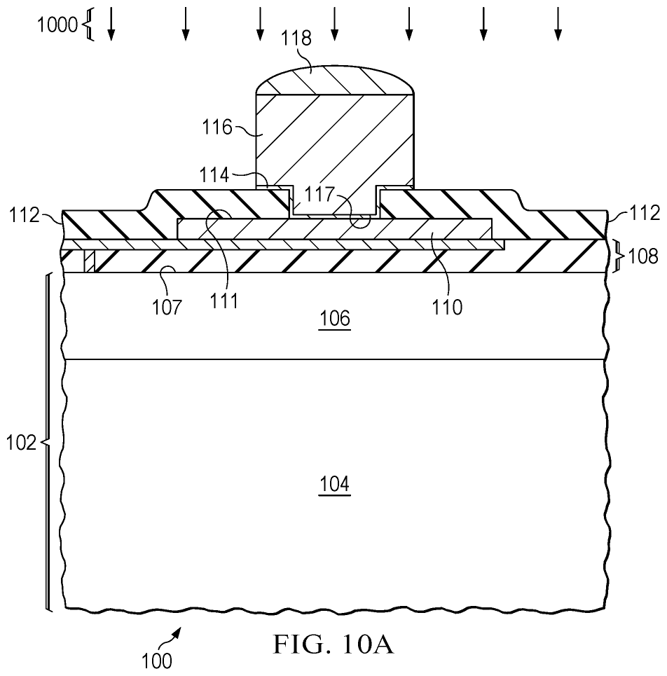

The method 200 continues at 216 with formation of the solder caps 118 along the top sides or ends of the metal posts 116 in each unit area of the processed wafer. At 216 in FIG. 2, a solder ball drop process is used to form the solder caps on the top sides of the metal posts 116. FIGS. 10 and 10A a show one example, in which a solder ball drop process 1000 is performed that drops a solder ball 118 on the top side of the illustrated metal post 116 using any suitable processing technique and equipment (not shown). In one example, the solder ball includes copper, tin, and silver. Each dropped solder ball 118 is initially dropped (FIG. 10) from a dispenser (not shown), and lands on the side of the metal post 116 (FIG. 10A).

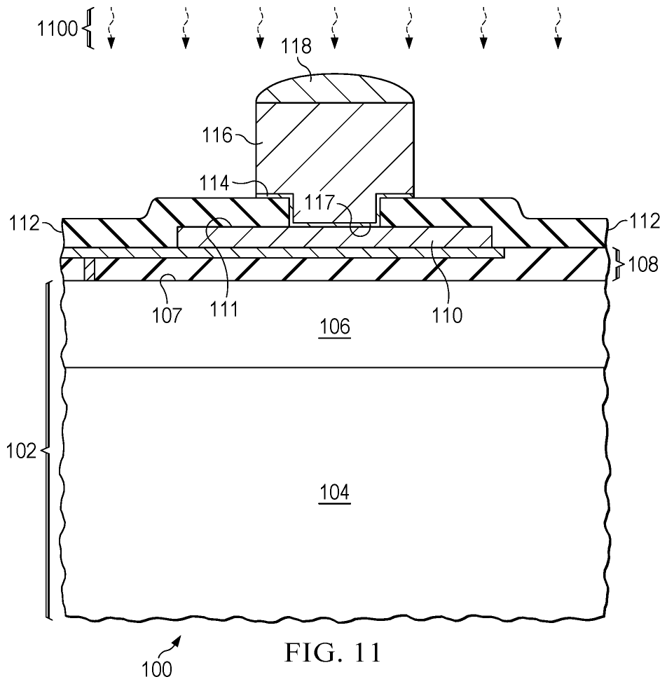

At 218 in FIG. 2, the solder cap formation continues with thermal solder reflow processing. FIG. 11 shows one example, in which a thermal reflow process 1100 is performed that reflows the solder cap 118 on the top side of the metal post 116.

The method 200 continues with die separation and packaging operations at 220 to 228 in FIG. 2. Die separation processing is performed at 222 separate the individual processed semiconductor dies 122 from the processed wafer 102. FIGS. 12 and 12A show one example, in which individual die areas 122 of the wafer 102 are separated from one another along lines 1202 shown in FIG. 12 by a die separation process 1200. In one example, laser dicing is used in which a laser (not shown) is translated along scribe streets between adjacent rows and columns of unit areas 122 along one side of the wafer 102 (e.g., from the bottom or backside in one example). The laser dicing creates fractures and cracks in the wafer 102, and the wafer 102 is installed on a carrier or tape structure. The tape is then stretched radially outward as shown in FIG. 12A to separate individual processed semiconductor dies 122 from one another and from the starting wafer structure where the individual semiconductor dies 122 each include one or more of the metal posts 116 and associated solder caps 118 as illustrated and described above.

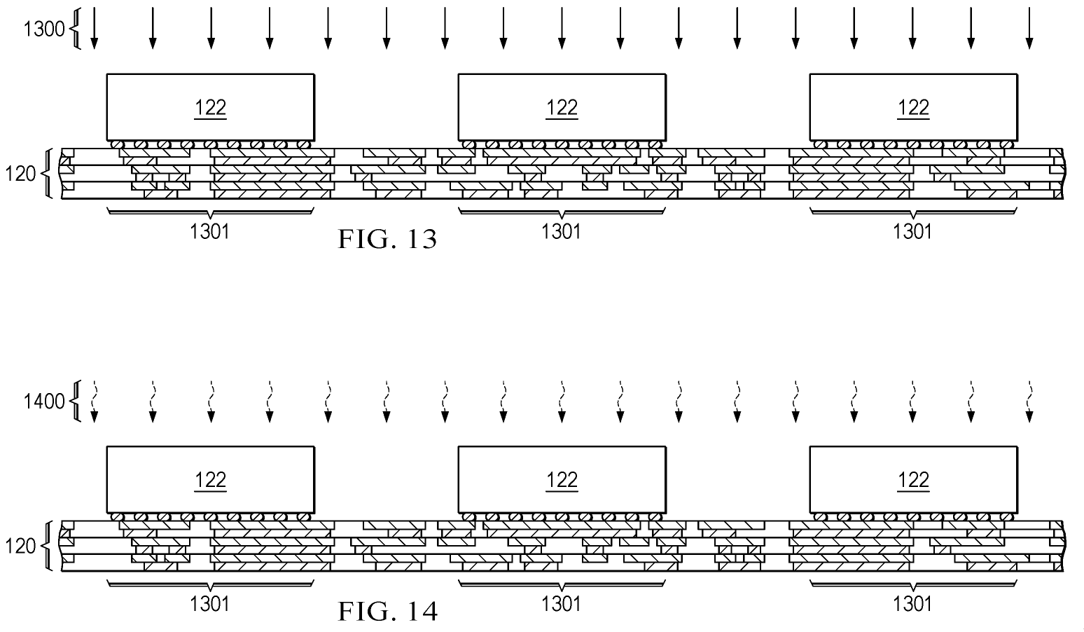

The separated semiconductor dies 122 are then used as components in a packaging operation at 222 to 228 in FIG. 2 in order to create packaged electronic devices 100. In the illustrated example, the semiconductor dies 122 are flip chip attached (e.g., soldered) to a substrate at 222 and 224 in FIG. 2. FIG. 13 shows one example, in which a flip chip die attach process 1300 is performed that attaches the metal posts 116 of the individual semiconductor dies 122 to respective top side conductive metal features on an upper level of a starting multilevel package substrate 120 in the form of a panel array having rows and columns of individual unit areas 1301. In one example, the die attach process 1300 uses automated pick and place equipment (not shown) that places individual semiconductor dies 122 in the corresponding unit areas 1301 of the panel array.

The method 200 continues at 224 in FIG. 2 with reflowing the solder caps 118 of the respective die terminals to form solder connections between the die terminals (e.g., the metal post 116) and the associated conductive features along the top side of the multilevel package substrate 100 in each unit area 1301 of the panel array structure. FIG. 14 shows one example, in which a thermal reflow process 1400 is performed that reflows the solder caps 118 at a suitable temperature (e.g., approximately 240 degrees C.) for an adequate amount of time to reflow the solder and create solder joints that electrically and mechanically interconnect the semiconductor dies 122 with the corresponding unit areas 1301 of the multilevel package substrate 120.

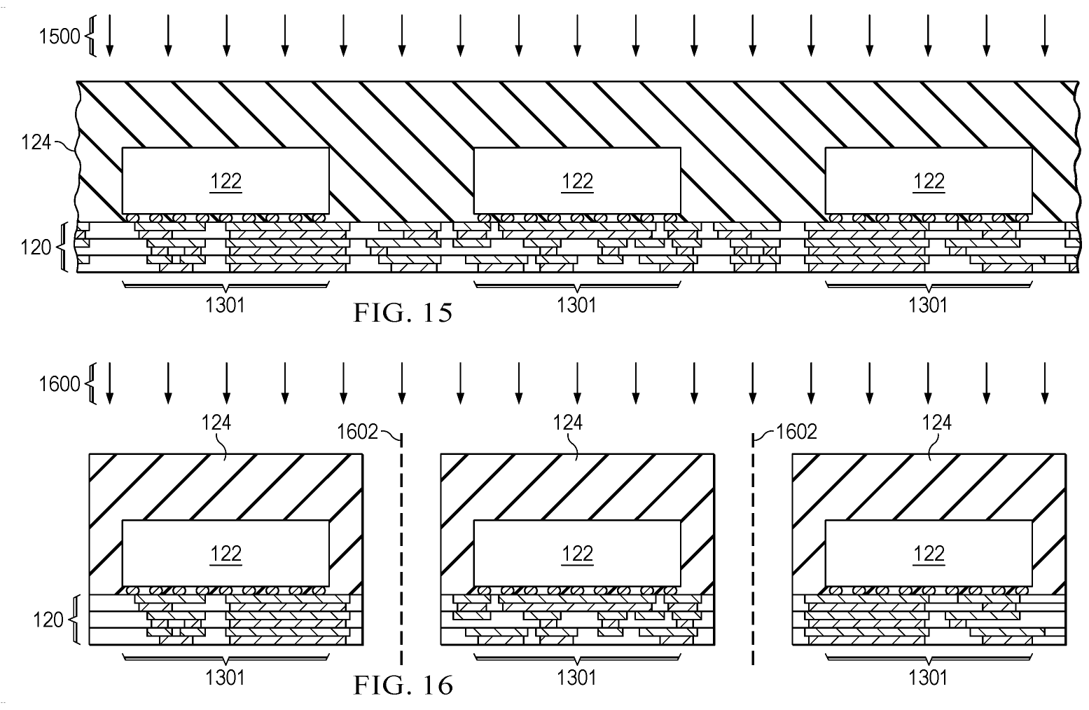

At 226 in FIG. 2, the method 200 continues with molding processing. FIG. 15 shows one example, in which a molding process 1500 is performed that forms a molded package structure 124 that encloses the semiconductor dies and extends to the exposed top side of the multilevel package substrate 120. In the illustrated example, a single mold cavity can be used to create a unitary molded structure 124 in all the unit areas 1301 of the panel array structure. In another implementation (not shown), multiple cavities can be used, each including one or more of the unit areas 1301.

At 228 in FIG. 2, the method 200 includes package separation processing to separate individual packaged electronic devices 100 from the panel array structure. FIG. 16 shows one example, in which a die separation process 1600 is performed that separates individual packaged electronic devices along lines 1602 between adjacent unit areas 1301. In one example, the die separation process 1600 includes cutting operations using any suitable techniques and equipment (not shown), such as saw cutting, laser cutting, etching, etc. to produce multiple instances of the packaged electronic device 100 illustrated and described above in connection with FIGS. 1 and 1A. The individual electronic devices 100 can then be installed in a host system, such as the system 1300 in FIG. 1A.

Modifications are possible in the described examples, and other implementations are possible, within the scope of the claims.

What is claimed is:

1. An electronic device, comprising:
a semiconductor die having a semiconductor surface layer;
a metallization structure on a side of the semiconductor surface layer and including a conductive feature;
a conductive terminal having a metal post, the conductive terminal having a first side contacting a side of the conductive feature; and
a solder cap on a second side of the conductive terminal.

2. The electronic device of claim 1, wherein the metal post includes copper.

3. The electronic device of claim 2, wherein the solder cap includes copper, tin and silver.

4. The electronic device of claim 2, wherein the conductive feature of the metallization structure includes aluminum.

5. The electronic device of claim 2, wherein the conductive terminal includes a copper layer that extends between the metal post and the conductive feature of the metallization structure.

6. The electronic device of claim 1, wherein the solder cap includes copper, tin and silver.

7. The electronic device of claim 1, wherein the conductive feature of the metallization structure includes aluminum.

8. The electronic device of claim 1, wherein the conductive terminal includes a copper layer that extends between the metal post and the conductive feature of the metallization structure.

9. The electronic device of claim 1, wherein the semiconductor surface layer includes gallium

10. The electronic device of claim 1, further comprising a polyimide layer on a portion of the conductive feature of the metallization structure, the polyimide layer contacting a portion of the metal post.

11. The electronic device of claim 1, wherein the second side of the conductive terminal is soldered to a lead frame or substrate.

12. A system, comprising:
a circuit board; and
an electronic device attached to the circuit board and comprising:
a lead frame or substrate;
a semiconductor die having a semiconductor surface layer;
a metallization structure on a side of the semiconductor surface layer and including a conductive feature;
a conductive terminal having a metal post, a first side, and an opposite second side, the first side of the conductive terminal contacting the first side of the conductive feature; and
a solder cap on a second side of the conductive terminal;
wherein the second side of the conductive terminal is soldered to the lead frame or substrate, and the lead frame or substrate is electrically connected to the circuit board.

13. The system of claim 12, wherein the solder cap includes copper, tin and silver.

14. The system of claim 12, wherein the conductive feature of the metallization structure includes aluminum.

15. The system of claim 12, wherein the conductive terminal includes a copper layer that extends between the metal post and the conductive feature of the metallization structure.

16. A method of fabricating an electronic device, the method comprising:
forming a copper layer on a portion of a conductive feature of a metallization structure of a wafer;
performing an electroplating process that forms a metal post on a first portion of the copper layer;
etching a second portion of the copper layer;
performing a solder ball drop process that forms a solder cap on a side of the metal post; and
separating from the wafer, a die that includes the metal post and the solder cap.

17. The method of claim 16, wherein the solder cap includes copper, tin and silver.

18. The method of claim 16, wherein the metal post includes copper.

19. The method of claim 16, wherein the wafer includes a gallium nitride semiconductor surface layer.

20. The method of claim 16, wherein the conductive feature of the metallization structure includes aluminum.
